(19) United States
(12) Patent Application Publication
(10) Pub. No.: US 2012/0280706 A1
(43) Pub. Date: Nov. 8, 2012

(54) CLEANING SHEET, CLEANING MEMBER, CLEANING METHOD, AND CONTINUITY TEST APPARATUS

(75) Inventors: Daisuke Uenda, Suzuka-shi (JP); Makoto Namikawa, Suzuka-shi (JP); Takeshi Matsumura, Suzuka-shi (JP)

(73) Assignee: C/O NITTO DENKO CORPORATION, Osaka (JP)

(21) Appl. No.: 13/464,861

(22) Filed: May 4, 2012

(30) Foreign Application Priority Data
May 6, 2011 (JP) 2011-103384

(51) Int. Cl. G01R 1/067; B08B 1/00; A47L 25/00; A47L 13/10

(52) U.S. Cl. 324/756.03; 15/209.1; 15/104.002; 134/6

(57) ABSTRACT

Provided is a cleaning unit for removing foreign matter adhering to a probe needle of a probe card for a continuity test, the cleaning unit being capable of effectively removing the foreign matter adhering to the probe needle without abrading the probe needle. A cleaning sheet of the present invention is a cleaning sheet, including a cleaning layer for removing foreign matter adhering to a probe needle of a probe card for a continuity test, in which the cleaning layer has an arithmetic average roughness Ra in conformity with JIS-B-0601 of 100 nm or less.

### BACKGROUND OF THE INVENTION

1. Field of the Invention

The present invention relates to a cleaning sheet having a cleaning layer for removing foreign matter adhering to a probe needle of a probe card for a continuity test. In addition, the present invention relates to a cleaning member having such cleaning sheet provided on a conveying member. In addition, the present invention relates to a cleaning method for a continuity test apparatus involving using such cleaning member. Further, the present invention relates to a continuity test apparatus cleaned by such cleaning method.

2. Description of the Related Art

A probe card has been used in a continuity test for a chip formed on a semiconductor wafer. In the continuity test, whether the chip is a conforming item or a nonconforming item is judged by bringing a probe needle of the probe card into contact with an electrode pad formed on the surface of the chip to measure a contact resistance value at the time. When the probe needle is brought into contact with, for example, an electrode pad formed of aluminum, a constant pressing force is applied, the tip of the probe needle scrapes a natural oxide film made of, for example, aluminum oxide formed on the surface of the electrode pad, the probe needle and the electrode pad are electrically connected to each other with reliability, and the check of the wafer is performed. When aluminum oxide, or the like having an insulating property, is scraped by the probe needle as described above, it adheres as foreign matter to the tip of the probe needle, and the contact resistance value when the probe needle is brought into contact with the electrode pad changes, which may hinder a subsequent continuity test. Therefore, the foreign matter adhering to the tip of the probe needle needs to be periodically removed.

The following method has been proposed as a method of removing the foreign matter adhering to the tip of the probe needle. The tip of the probe needle is brought into contact with a layer obtained by dispersing an abrasive material such as a diamond powder, alumina, silicon carbide, or glass in a resin or a layer obtained by fixing the abrasive material to the resin with an adhesive (see, for example, Japanese Patent Application Laid-open No. Hei 7-244074, Japanese Patent Application Laid-open No. Hei 10-300777, and Japanese Patent Application Laid-open No. Hei 10-339766).

However, the method of removing the foreign matter including bringing the tip of the probe needle into contact with a cleaning layer containing the abrasive material such as a diamond powder shortens the life of the probe card because the probe needle itself is abraded by the abrasive material upon its cleaning. In particular, in recent years, a probe card provided with several tens of thousands of probe needles has started to be used in association with the refinement of a chip, and hence the probe card has become extremely expensive. Accordingly, cleaning means for effectively removing foreign matter adhering to a probe needle without abrading the probe needle has been strongly requested.

### SUMMARY OF THE INVENTION

An object of the present invention is to provide cleaning means for removing foreign matter adhering to a probe needle of a probe card for a continuity test, the cleaning means being capable of effectively removing the foreign matter adhering to the probe needle without abrading the probe needle.

The present invention provides a cleaning sheet. The cleaning sheet of the present invention is a cleaning sheet, including a cleaning layer for removing foreign matter adhering to a probe needle of a probe card for a continuity test, in which the cleaning layer has an arithmetic average roughness Ra in conformity with JIS-B-0601 of 100 nm or less.

In a preferred embodiment, the cleaning layer has a dynamic hardness of 0.0001 to 0.1.

In a preferred embodiment, the cleaning sheet of the present invention includes the cleaning layer on one surface of a support.

In a preferred embodiment, the cleaning sheet further includes a pressure-sensitive adhesive layer on a surface of the support opposite to the cleaning layer.

The present invention further provides a cleaning member. The cleaning member of the present invention includes the cleaning sheet of the present invention provided on a conveying member.

The present invention further provides a cleaning method for a continuity test apparatus. The cleaning method for a continuity test apparatus of the present invention includes conveying the cleaning member of the present invention into a continuity test apparatus including a probe card for a continuity test to remove foreign matter adhering to a probe needle of the probe card for a continuity test.

The present invention further provides a continuity test apparatus. The continuity test apparatus of the present invention is a continuity test apparatus, which is cleaned by the cleaning method of the present invention.

According to the present invention, there can be provided a cleaning sheet having a cleaning layer for removing foreign matter adhering to a probe needle of a probe card for a continuity test, the cleaning sheet being capable of effectively removing the foreign matter adhering to the probe needle without abrading the probe needle. In addition, there can be provided a cleaning member having such cleaning sheet provided on a conveying member. In addition, there can be provided a cleaning method for a continuity test apparatus involving using such cleaning member. Further, there can be provided a continuity test apparatus cleaned by such cleaning method.

### BRIEF DESCRIPTION OF THE DRAWINGS

In the accompanying drawings:

FIG. 1 illustrates an example of a schematic sectional view of one embodiment of a cleaning sheet of the present invention;

FIG. 2 illustrates an example of a schematic sectional view of another embodiment of the cleaning sheet of the present invention;

FIG. 3 illustrates an example of a schematic sectional view of another embodiment of the cleaning sheet of the present invention;

FIG. 4 illustrates an example of a schematic sectional view of another embodiment of the cleaning sheet of the present invention;

FIG. 5 illustrates an example of a schematic sectional view of another embodiment of the cleaning sheet of the present invention;

FIG. 6 illustrates an example of a schematic sectional view of another embodiment of the cleaning sheet of the present invention;

FIG. 7 illustrates an example of a schematic sectional view of one embodiment of a cleaning member of the present invention;

FIG. 8 illustrates an example of a schematic sectional view of another embodiment of the cleaning member of the present invention;

FIG. 9 illustrates an example of a schematic sectional view of another embodiment of the cleaning member of the present invention; and

FIGS. 10A and 10B illustrate examples of schematic sectional views of one embodiment of a cleaning method for a continuity test apparatus of the present invention.

### DETAILED DESCRIPTION OF THE PREFERRED EMBODIMENTS

### 1. Cleaning Sheet

A cleaning sheet of the present invention is a cleaning sheet having a cleaning layer for removing foreign matter adhering to a probe needle of a probe card for a continuity test.

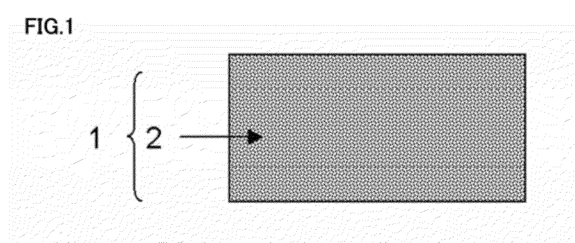

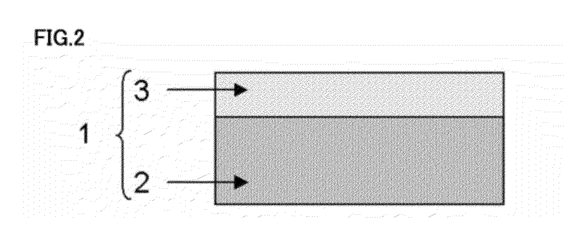

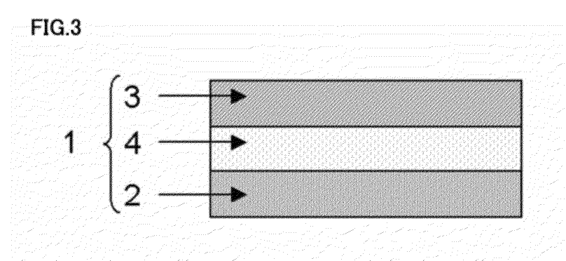

Any appropriate embodiment can be adopted for the cleaning sheet of the present invention as long as the cleaning sheet has the cleaning layer. As illustrated in FIG. 1, a cleaning sheet 1 may be formed only of a cleaning layer 2. As illustrated in FIG. 2, the cleaning sheet 1 may be formed of the cleaning layer 2 and a pressure-sensitive adhesive layer 3. As illustrated in FIG. 3, the cleaning sheet 1 may be formed of the cleaning layer 2, the pressure-sensitive adhesive layer 3, and a support 4.

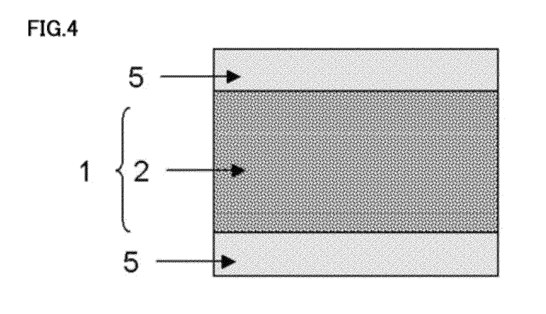

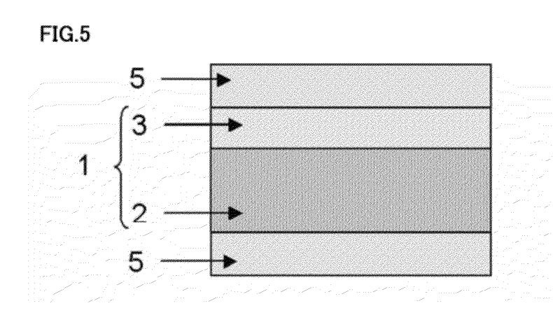

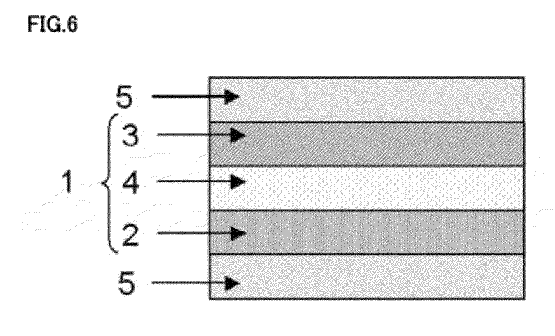

The cleaning sheet of the present invention may include a separator. As illustrated in FIG. 4, separators 5 may be provided for both surfaces of the cleaning sheet 1 formed only of the cleaning layer 2. As illustrated in FIG. 5, the separators 5 may be provided for both surfaces of the cleaning sheet 1 formed of the cleaning layer 2 and the pressure-sensitive adhesive layer 3. As illustrated in FIG. 6, the separators 5 may be provided for both surfaces of the cleaning sheet 1 formed of the cleaning layer 2, the pressure-sensitive adhesive layer 3, and the support 4.

### <1-1. Cleaning Layer>

The cleaning layer in the cleaning sheet of the present invention has an arithmetic average roughness Ra in conformity with JIS-B-0601 of 100 nm or less, preferably 90 nm or less, more preferably 80 nm or less, still more preferably 50 nm or less, particularly preferably 30 nm or less. A lower limit for the arithmetic average roughness Ra is preferably 1 nm or more. As long as the arithmetic average roughness Ra of the cleaning layer in the cleaning sheet of the present invention falls within the range, the cleaning sheet can be made to effectively remove foreign matter adhering to a probe needle without abrading the probe needle.

The cleaning layer in the cleaning sheet of the present invention has a dynamic hardness of preferably 0.0001 to 0.1, more preferably 0.0002 to 0.05, still more preferably 0.0003 to 0.03, and particularly preferably 0.004 to 0.02. As long as the dynamic hardness of the cleaning layer in the cleaning sheet of the present invention falls within the above range, the cleaning sheet can be additionally made to effectively remove the foreign matter adhering to the probe needle without abrading the probe needle. In particular, when the dynamic hardness of the cleaning layer in the cleaning sheet of the present invention is less than 0.0001, the cleaning layer is so soft that a component of the cleaning layer may adhere to the probe needle. Further, the cleaning layer expresses a pressure-sensitive adhesive strength and hence the probe needle is captured by the cleaning layer, which may lead to the breakage of the probe needle. In addition, when the dynamic hardness of the cleaning layer in the cleaning sheet of the present invention exceeds 0.1, the cleaning layer becomes hard and hence the probe needle no longer pierces through the cleaning layer. Accordingly, there is a possibility that the layer cannot exert foreign matter-removing performance.

The cleaning layer in the cleaning sheet of the present invention can be constituted of any appropriate material. Examples of such a material include a thermoplastic resin, a thermosetting resin, a photocurable resin, and a silicone resin. Only one such kind of material may be used, or two or more kinds thereof may be used.

Examples of the thermoplastic resin include a natural rubber, a butyl rubber, an isoprene rubber, a chloroprene rubber, an ethylene-vinyl acetate copolymer, an ethylene-acrylic acid copolymer, an ethylene-acrylic acid ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamide-imide resin, and a fluorine resin. Only one such kind of thermoplastic resin may be used, or two or more kinds thereof may be used. Of those thermoplastic resins, a particularly preferred resin is such a resin that has a small ionic impurity content, high heat resistance, and ability to secure the reliability of a semiconductor device.

Any appropriate acrylic resin can be adopted as the acrylic resin. A monomer for forming such an acrylic resin is, for example, a (meth)acrylic acid ester having a linear or branched alkyl group having 30 or less carbon atoms, and is preferably, for example, a (meth)acrylic acid ester having a linear or branched alkyl group having 4 to 18 carbon atoms. Only one such kind of acrylic resin may be used, or two or more kinds thereof may be used. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group. It should be noted that the term “(meth)acrylic acid” in the specification refers to at least one of acrylic acid and methacrylic acid.

Examples of the other monomer for forming the acrylic resin include: carboxyl group-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methyl acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group-containing monomers such as 2-hydroxyethylacryloyl phosphate.

Examples of the thermosetting resin include an epoxy resin, a phenol resin, an amino resin, an unsaturated polyester resin, a polyurethane resin, and a polyimide resin. Only one such kind of thermosetting resin may be used, or two or more kinds thereof may be used. Of the thermosetting resins, a thermosetting resin having a small ionic impurity, or the like, which may corrode a semiconductor device, is preferred.

Any appropriate epoxy resin can be adopted as the epoxy resin. Examples of such an epoxy resin include: bifunctional epoxy resins and polyfunctional epoxy resins of a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolac type, an ortho-cresol novolac type, a trishydroxyphenylmethane type, and a tetraphenylolethane type; and epoxy resins of a hydantoin type, a triglycidyl isocyanurate type, and a glycidylamine type. Only one such kind of epoxy resin may be used, or two or more kinds thereof may be used. Of such epoxy resins, a novolac type epoxy resin, a biphenyl type epoxy resin, a trishydroxyphenylmethane type epoxy resin, and a tetraphenylolethane type epoxy resin are particularly preferred because these epoxy resins are each rich in reactivity with a phenol resin as a curing agent, and are each excellent in heat resistance or the like.

Two kinds of epoxy resin, for example a resin that is a solid at normal temperature and a resin that is a liquid at normal temperature, can be used in combination as the epoxy resin. The combined use of the epoxy resin that is a solid at normal temperature and the epoxy resin that is a liquid at normal temperature alleviates the brittleness of the resultant epoxy resin and hence can improve workability.

The phenol resin can act as a curing agent for the epoxy resin. Any appropriate phenol resin can be adopted as the phenol resin, and examples of such a phenol resin include: novolac type phenol resins such as a phenol novolac resin, a phenol aralkyl resin, a cresol novolac resin, a tert-butyl phenol novolac resin, and a nonylphenol novolac resin; resol type phenol resins; and polyoxystyrenes such as a polyparaoxystyrene. Only one such kind of phenol resin may be used, or two or more kinds thereof may be used. Of such phenol resins, the phenol novolac resin and the phenol aralkyl resin are particularly preferred because these phenol resins can each improve the connection reliability of the semiconductor device.

When using an epoxy resin and a phenol resin, a compounding ratio between them is, for example, such a ratio that the amount of a hydroxyl group in the phenol resin per 1 equivalent of an epoxy group in the epoxy resin component is preferably 0.5 to 2.0 equivalents, more preferably 0.8 to 1.2 equivalents. When the compounding ratio deviates from the above-mentioned range, a sufficient curing reaction does not proceed, and hence the characteristics of an epoxy resin-cured product may be apt to deteriorate.

Any appropriate polyimide resin can be adopted as the polyimide resin. Examples of such a polyimide resin include a thermosetting polyimide resin and a thermoplastic polyimide resin. Only one such kind of polyimide resin may be used, or two or more kinds thereof may be used. The polyimide resin is generally a heat-resistant resin obtained by the dehydration condensation (imidation) of a polyamic acid as a precursor thereof. The polyamic acid can be obtained by causing a diamine component and an acid anhydride component to react with each other at a substantially equimolar ratio in any appropriate organic solvent.

Any appropriate diamine can be adopted as the diamine. Examples of such a diamine include aliphatic diamines and aromatic diamines. Only one such kind of diamine may be used, or two or more kinds thereof may be used. Examples of the aliphatic diamines include ethylene diamine, hexamethylene diamine, 1,8-diaminooctane, 1,10-diaminodecane, 1,12-diaminododecane, 4,9-dioxa-1,12-diaminododecane, and 1,3-bis(3-aminopropyl)-1,1,3,3-tetramethyldisiloxane(α,ω-bisaminopropyltetramethyl disiloxane). Examples of the aromatic diamines include 4,4′-diaminodiphenylether, 3,4′-diaminodiphenylether, 3,3′-diaminodiphenylether, m-phenylenediamine, p-phenylenediamine, 4,4′-diaminodiphenyl propane, 3,3′-diaminodiphenyl methane, 4,4′-diaminodiphenyl sulfide, 3,3′-diaminodiphenyl sulfide, 4,4′-diaminodiphenyl sulfone, 3,3′-diaminodiphenyl sulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone.

Any appropriate acid anhydride can be adopted as the acid anhydride. Examples of such an acid anhydride include a tetracarboxylic dianhydride. Examples of such a tetracarboxylic dianhydride include 3,3′,4,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 4,4′-oxydiphthalic dianhydride, 2,2-bis(2,3-dicarboxyphenyl)hexafluoropropane dianhydride, 2,2-bis(3,4-dicarboxyphenyl)hexafluoropropane dianhydride (6FDA), bis(2,3-dicarboxyphenyl)methane dianhydride, bis(3,4-dicarboxyphenyl)methane dianhydride, bis(2,3-dicarboxyphenyl) sulfone dianhydride, bis(3,4-dicarboxyphenyl)sulfone dianhydride, pyromellitic dianhydride, and ethyleneglycol bistrimellitic dianhydride. Only one such kind of acid anhydride may be used, or two or more kinds thereof may be used.

Any appropriate solvent can be adopted as the solvent in which the diamine and the acid anhydride are caused to react with each other. Examples of such a solvent include N,N-dimethylacetamide, N-methyl-2-pyrrolidone, N,N-dimethylformamide, and cyclopentanone. Only one such kind of solvent may be used, or two or more kinds thereof may be used. Any such solvent can be used as a mixture with a nonpolar solvent such as toluene or xylene in order that the solubility of a raw material or a resin may be adjusted.

Any appropriate method can be adopted as a method for the dehydration condensation (imidation) of the polyamic acid. Examples of such a method include a heating imidation method, an azeotropic dehydration method, and a chemical imidation method. Of such methods, the heating imidation method is preferred and a heating temperature is preferably 150° C. or more. In addition, in the heating imidation method, a treatment is preferably performed under an inert atmosphere, e.g., under a nitrogen atmosphere or in a vacuum in order that the oxidation degradation of a resin may be prevented. Thus, a volatile component remaining in the resin can be completely removed. In addition, in the case where a tetracarboxylic dianhydride and a diamine are caused to react with each other, particularly when a diamine containing a butadiene-acrylonitrile copolymer skeleton is used, the reaction is preferably performed at a temperature of 100° C. or more. Thus, gelation can be prevented.

A thermosetting catalyst may be incorporated into the material constituting the cleaning layer in the cleaning sheet of the present invention. The content of the thermosetting catalyst is, for example, preferably 0.01 to 5 parts by weight, more preferably 0.05 to 3 parts by weight, still more preferably 0.1 to 1 parts by weight with respect to 100 parts by weight of a resin as the material constituting the cleaning layer. When the content of the thermosetting catalyst is set to 0.01 parts by weight or more with respect to 100 parts by weight of the resin as the material constituting the cleaning layer, the cleaning effect of the cleaning layer can be favorably expressed. When the content of the thermosetting catalyst is set to 5 parts by weight or less with respect to 100 parts by weight of the resin as the material constituting the cleaning layer, a reduction in the storage stability of the cleaning layer can be suppressed. Any appropriate thermosetting catalyst can be adopted as the thermosetting catalyst. Examples of such a thermosetting catalyst include an imidazole-based compound, a triphenylphosphine-based compound, an amine-based compound, a triphenylborane-based compound, and a trihalogen borane-based compound. Only one such kind of thermosetting catalyst may be used, or two or more kinds thereof may be used.

Any appropriate imidazole-based compound can be adopted as the imidazole-based compound. Examples of such an imidazole-based compound include 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-phenylimidazolium trimeritate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine-isocyanuric acid adduct, 2-phenyl-4,5-dihydroxymethylimidazole, and 2-phenyl-4-methyl-5-hydroxymethylimidazole. Only one such kind of imidazole-based compound may be used, or two or more kinds thereof may be used.

Any appropriate triphenylphosphine-based compound can be adopted as the triphenylphosphine-based compound. Examples of such a triphenylphosphine-based compound include triorganophosphines such as triphenylphosphine, tributylphosphine, tri(p-methylphenyl)phosphine, tri(nonylphenyl)phosphine, and diphenyltolylphosphine; tetraphenylphosphonium bromide; a methyltriphenylphosphonium compound; methyltriphenylphosphonium chloride; a methoxymethyltriphenylphosphonium compound; and benzyltriphenylphosphonium chloride. Only one such kind of triphenylphosphine-based compound may be used, or two or more kinds thereof may be used. The triphenylphosphine-based compound is preferably a compound that substantially shows non-solubility in an epoxy resin. When the compound is substantially non-soluble in the epoxy resin, excessive progress of thermal curing can be suppressed. A thermosetting catalyst having a triphenylphosphine structure and substantially showing non-solubility in the epoxy resin is, for example, a methyltriphenylphosphonium compound. It should be noted that the term “non-solubility” means that the thermosetting catalyst formed of the triphenylphosphine-based compound is insoluble in a solvent formed of the epoxy resin, and more specifically, means that the catalyst dissolves at less than 10 wt % in the solvent in the temperature range of 10 to 40° C.

Any appropriate triphenylborane-based compound can be adopted as the triphenylborane-based compound. Only one such kind of triphenylborane-based compound may be used, or two or more kinds thereof may be used. In addition, a compound further having a triphenylphosphine structure is also included in the triphenylborane-based compound. Any appropriate compound can be adopted as the compound having a triphenylphosphine structure and a triphenylborane structure. Examples of such a compound having a triphenylphosphine structure and a triphenylborane structure include tetraphenylphosphonium tetraphenylborate, tetraphenylphosphonium tetra-p-triborate, benzyltriphenylphosphonium tetraphenylborate, and triphenylphosphine-triphenylborane.

Any appropriate amine-based compound can be adopted as the amine-based compound. Examples of such a amine-based compound include monoethanolamine trifluoroborate and dicyandiamide. Only one such kind of amine-based compound may be used, or two or more kinds thereof may be used.

Any appropriate trihalogen borane-based compound can be adopted as the trihalogen borane-based compound. Examples of such a trihalogen borane-based compounds include trichloroborane. Only one such kind of trihalogen borane-based compound may be used, or two or more kinds thereof may be used.

A cross-linking agent may be incorporated into the material constituting the cleaning layer in the cleaning sheet of the present invention. The incorporation of the cross-linking agent improves the cleaning effect under a high temperature and hence can achieve an improvement in the heat resistance of the layer. Any appropriate cross-linking agent can be adopted as a cross-linking agent. Examples of such a cross-linking agent include polyisocyanate compounds such as tolylene diisocyanate, diphenylmethane diisocyanate, p-phenylene diisocyanate, 1,5-naphthalene diisocyanate, and an adduct of a polyhydric alcohol and a diisocyanate. Only one such kind of cross-linking agent may be used, or two or more kinds thereof may be used. The content of any such cross-linking agent is preferably 0.05 to 7 parts by weight with respect to 100 parts by weight of the resin as the material constituting the cleaning layer. When the amount of the cross-linking agent is larger than 7 parts by weight with respect to 100 parts by weight of the resin as the material constituting the cleaning layer, the cleaning effectiveness of the cleaning layer may be reduced. When the amount of the cross-linking agent is smaller than 0.05 parts by weight with respect to 100 parts by weight of the resin as the material constituting the cleaning layer, the cohesive strength of the cleaning layer may be insufficient.

Any appropriate photocurable resin can be adopted as the photocurable resin as long as the photocurable resin has such nature as to cure with active energy to have a three-dimensionally networked molecular structure. Such photocurable resin is preferably, for example, a resin obtained by incorporating, into a pressure-sensitive adhesive polymer, a polymerizable unsaturated compound having one or more unsaturated double bonds in a molecule thereof and a polymerization initiator. Here, the compound having one or more unsaturated double bonds in a molecule thereof (hereinafter referred to as “polymerizable unsaturated compound”) is preferably a low-molecular weight body that is nonvolatile and has a weight average molecular weight of 10,000 or less, and is more preferably a low-molecular weight body having a weight average molecular weight of 5,000 or less in order that the three-dimensional networking at the time of the curing may be efficiently performed. Examples of such a polymerizable unsaturated compound include phenoxypolyethyleneglycol(meth)acrylate, ε-caprolactone(meth)acrylate, polyethyleneglycol di(meth)acrylate, polypropyleneglycol di(meth)acrylate, trimethylolpropane tri(meth)acrylate, dipentaerythritol hexa(meth)acrylate, urethane meth(acrylate), epoxy(meth)acrylate, and oligoester(meth)acrylate. Only one such kind of such polymerizable unsaturated compound may be used, or two or more kinds thereof may be used.

The pressure-sensitive adhesive polymer is, for example, an acrylic polymer using, as a main monomer, at least one of (meth)acrylic acid and a (meth)acrylic acid ester selected from acrylic acid, an acrylic acid ester, methacrylic acid, and a methacrylic acid ester. Such an acrylic polymer can be cured with an active energy by introducing an unsaturated double bond into a molecule of the acrylic polymer through, for example, the following procedure. A compound having two or more unsaturated double bonds in a molecule thereof is used as a copolymerizable monomer in the synthesis of the acrylic polymer. Alternatively, a compound having an unsaturated double bond in a molecule thereof is chemically bonded to the acrylic polymer after the synthesis by a reaction between functional groups.

A polymerization initiator may be incorporated into the material constituting the cleaning layer in the cleaning sheet of the present invention. Any appropriate polymerization initiator can be adopted as the polymerization initiator. Examples of such a polymerization initiator include, when using heat as the active energy, thermal polymerization initiators such as benzoyl peroxide and azobisisobutyronitrile, and when using light as the active energy, photopolymerization initiators such as benzoyl, benzoin ethyl ether, dibenzyl, isopropyl benzoin ether, benzophenone, Michler's ketone, chlorothioxanthone, dodecylthioxanthone, dimethylthioxanthone, acetophenone diethyl ketal, benzyl dimethyl ketal, α-hydroxycyclohexylphenylketone, 2-hydroxymethylphenylpropane, and 2,2-dimethoxy-2-phenylacetophenone. Only one such kind of polymerization initiator may be used, or two or more kinds thereof may be used.

Any appropriate silicone resin can be adopted as the silicone resin. Only one such kind of silicone resin may be used, or two or more kinds thereof may be used. When the silicone resin is adopted as the material constituting the cleaning layer in the cleaning sheet of the present invention, a heat resistance of the cleaning layer is improved, and a storage modulus of elasticity and adhesive strength under a high temperature of the cleaning layer can achieve suitable values. Examples of such a silicone resin include a peroxide cross-linking silicone-based adhesive, an addition reaction curable silicone-based adhesive, a dehydrogenation reaction curable silicone-based adhesive, and a moisture-curable silicone-based adhesive. Of these silicone resins, the addition reaction-type silicone-based adhesive is preferred because of its small impurity content.

Any appropriate other additive can be incorporated into the material constituting the cleaning layer in the cleaning sheet of the present invention as required. Examples of such other additives include a flame retardant, a silane coupling agent, and an ion trapping agent. Examples of the flame retardant include antimony trioxide, antimony pentoxide, and a brominated epoxy resin. Examples of the silane coupling agent include β3,4-epoxycyclohexyl)ethyltrimethoxysilane, γ-glycidoxypropyltrimethoxysilane, and γ-glycidoxypropylmethyldiethoxysilane. Examples of the ion trapping agent include hydrotalcites and bismuth hydroxide. Only one such kind of other additive may be used, or two or more kinds thereof may be used.

The material constituting the cleaning layer in the cleaning sheet of the present invention is preferably free of any abrasive. When the abrasive is incorporated, the probe needle is abraded and hence the service life of the probe needle may be shortened.

The cleaning layer in the cleaning sheet of the present invention preferably has a thickness of 50 to 300 μm. When the thickness of the cleaning layer is smaller than 50 μm, there is a possibility that upon piercing of the cleaning layer with the probe needle, the probe needle penetrates the cleaning layer to reach, for example, a conveying member, and the penetration may lead to the breakage of the probe needle. In addition, when the thickness of the cleaning layer is 300 μm or more, the accuracy of the thickness of the cleaning layer deteriorates, and hence the probe needle may contact the cleaning layer in some portions of the cleaning layer but the probe needle may not contact the cleaning layer in other portions of the cleaning layer.

### <1-2. Pressure-Sensitive Adhesive Layer>

The pressure-sensitive adhesive layer in the cleaning sheet of the present invention has a 90° peel strength (for example, a release strength) with respect to a silicon wafer (for example, a mirror surface of the silicon wafer) of preferably 0.01 to 10 N/10 mm width, more preferably 0.03 to 8 N/10 mm width, still more preferably 0.05 to 5 N/10 mm width. When the 90° peel strength (for example, a release strength) is excessively high, the cleaning sheet may tear upon its release and removal from a substrate or the like. When the 90° peel strength (for example, a release strength) is excessively low, the layer may be unable to achieve a sufficient pressure-sensitive adhesive strength.

The pressure-sensitive adhesive layer in the cleaning sheet of the present invention can be constituted of any appropriate material. Examples of such a material include typical pressure-sensitive adhesives such as an acrylic pressure-sensitive adhesive and a rubber-based pressure-sensitive adhesive. Only one such kind of material may be used, or two or more kinds thereof may be used. Of such materials, the acrylic pressure-sensitive adhesive is preferred, and an acrylic pressure-sensitive adhesive using, as a main agent, an acrylic polymer containing a component having a weight average molecular weight of 100,000 or less at 10 wt % or less is more preferred. Such an acrylic polymer can be synthesized by subjecting a monomer mixture to a polymerization reaction, the monomer mixture using a (meth)acrylic acid alkyl ester as a main monomer and containing any other copolymerizable monomer added to the monomer as required.

The pressure-sensitive adhesive layer in the cleaning sheet of the present invention has a thickness of preferably 1 to 100 μm, more preferably 3 to 50 μm.

### <1-3. Support>

The support in the cleaning sheet of the present invention can be constituted of any appropriate material. Examples of such a material include: polyolefins such as a low-density polyethylene, a linear polyethylene, a medium-density polyethylene, a high-density polyethylene, an ultra-low density polyethylene, a random-copolymerized polypropylene, a block-copolymerized polypropylene, a homopolypropylene, a polybutene, and a polymethylpentene; an ethylene-vinyl acetate copolymer; an ionomer resin; an ethylene-(meth)acrylic acid copolymer; an ethylene-(meth)acrylic acid ester (random, alternating) copolymer; an ethylene-butene copolymer; an ethylene-hexene copolymer; a polyurethane; polyesters such as a polyethylene terephthalate and a polyethylene naphthalate; polycarbonates; polyimides; polyetheretherketones; polyetherimides; polyamides; fully aromatic polyamides; polyphenylsulfides; aramid (paper); glass; glass cloth; fluorine resins; polyvinyl chlorides; polyvinylidene chlorides; cellulose-based resins; silicone resins, metal (for example, foil); and paper. Only one such kind of material may be used, or two or more kinds thereof may be used.

The surface of the support in the cleaning sheet of the present invention may be subjected to any appropriate surface treatment in order that its adhesiveness with an adjacent layer, retaining performance, and the like may be improved. Examples of such a surface treatment include: chemical or physical treatments such as a chromic acid treatment, ozone exposure, flame exposure, high-voltage electric exposure, and an ionized radiation treatment; and a coating treatment with an undercoating agent.

The support in the cleaning sheet of the present invention preferably has a thickness of 5 to 200 μm.

### <1-4. Separator>

The separator in the cleaning sheet of the present invention can be constituted of any appropriate material. Such materials include, for example, a plastic film subjected to a release treatment with a releasing agent or the like. Examples of the releasing agent include silicone-, long-chain alkyl-, fluorine-, aliphatic amide-, and silica-based releasing agents. Examples of the plastic film include a polyolefin film such as a polyethylene, a polypropylene, a polybutene, a polybutadiene, or a polymethylpentene film. Other examples of the plastic film include films made of polyvinyl chlorides; vinyl chloride copolymers; polyethylene terephthalates; polybutylene terephthalates; polyurethanes; ethylene-vinyl acetate copolymers; ionomer resins; ethylene-(meth)acrylic acid copolymers; ethylene-(meth)acrylic acid ester copolymers; polystyrenes; and polycarbonates.

The separator in the cleaning sheet of the present invention preferably has a thickness of 5 to 200 μm.

### 2. Cleaning Member

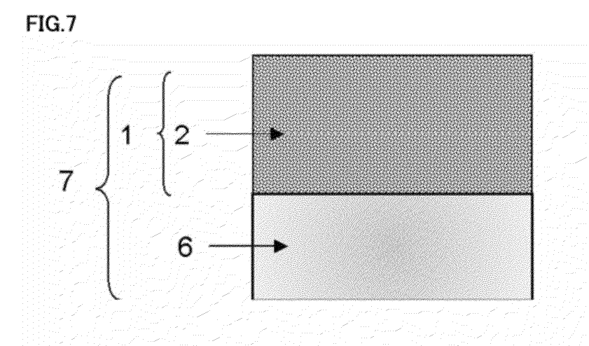

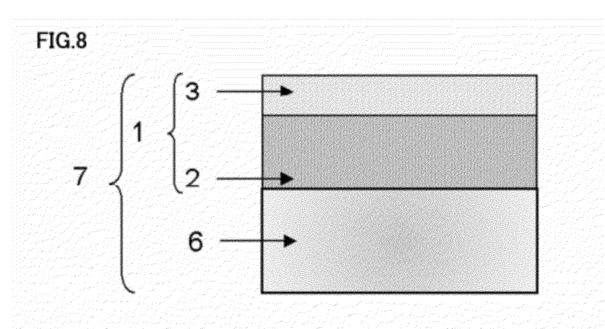

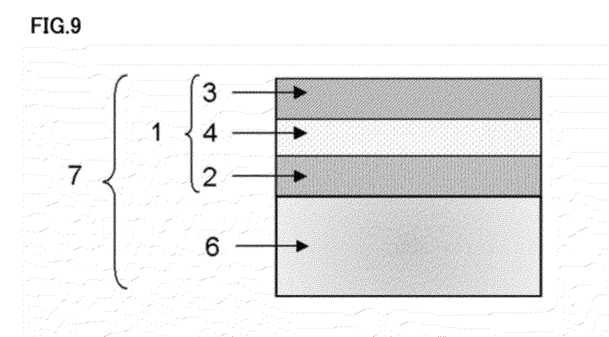

A cleaning member of the present invention has the cleaning sheet of the present invention provided on a conveying member. As illustrated in FIG. 7, a cleaning member 7 of the present invention may be such that the cleaning sheet 1 formed only of the cleaning layer 2 is provided on a conveying member 6. As illustrated in FIG. 8, the cleaning member 7 of the present invention may be such that the cleaning sheet 1 formed of the cleaning layer 2 and the pressure-sensitive adhesive layer 3 is provided on the conveying member 6. As illustrated in FIG. 9, the cleaning member 7 of the present invention may be such that the cleaning sheet 1 formed of the cleaning layer 2, the pressure-sensitive adhesive layer 3, and the support 4 is provided on the conveying member 6.

Any appropriate conveying member can be adopted as the conveying member as long as foreign matter adhering to a probe needle of a probe card for a continuity test can be removed by: providing the cleaning sheet of the present invention on the conveying member; and conveying the sheet into a continuity test apparatus including the probe card for a continuity test. Examples of the conveying member include: semiconductor wafers (for example, a silicon wafer); substrates for flat-panel displays such as an LCD and a PDP; and substrates for a compact disc, an MR head, and the like. The thickness of the conveying member can be appropriately selected depending on the application.

### 3. Cleaning Method for Continuity Test Apparatus

A cleaning method for a continuity test apparatus of the present invention includes conveying the cleaning member of the present invention into a continuity test apparatus including a probe card for a continuity test to remove foreign matter adhering to a probe needle of the probe card for a continuity test.

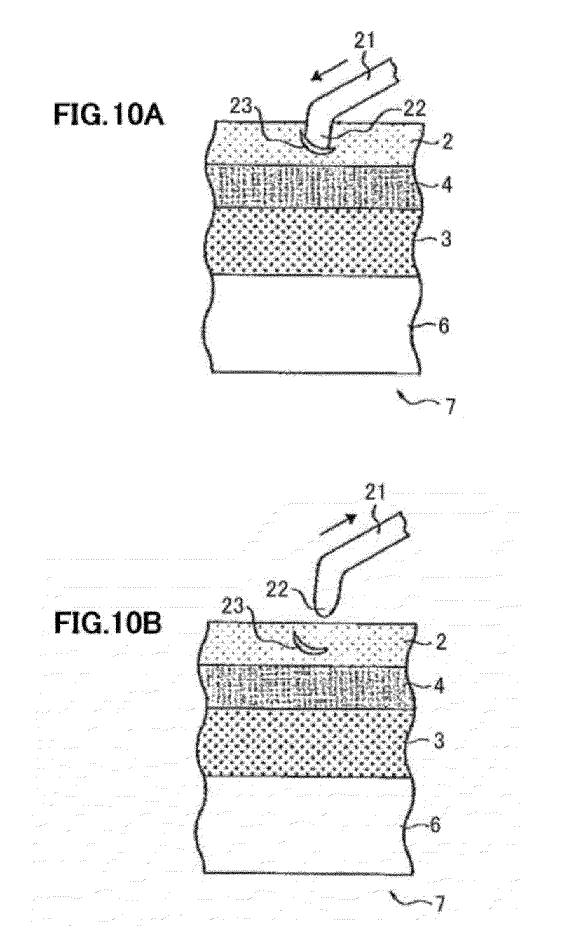

FIGS. 10A-10B illustrate one embodiment of the cleaning method for a continuity test apparatus of the present invention. FIGS. 10A-10B illustrate an example in which the cleaning member 7 of the present invention has the cleaning layer 2, the support 4, the pressure-sensitive adhesive layer 3, and the conveying member 6 in the stated order. First, the cleaning member 7 of the present invention is mounted on any appropriate fixing seat, and then the cleaning member 7 of the present invention is placed so as to be opposite to the probe card of the continuity test apparatus. Next, as illustrated in FIG. 10A, the cleaning layer 2 is pierced with a distal tip portion 22 of a probe needle 21. After that, as illustrated in FIG. 10B, the probe needle 21 is pulled out. Through the foregoing operation, foreign matter 23 such as aluminum oxide adhering to the distal tip portion 22 of the probe needle 21 remains in the cleaning layer 2, and hence the foreign matter 23 is removed from the distal tip portion 22 of the probe needle 21. Although the operation is typically repeated a predetermined number of times (e.g., 10 to 30 times), the following approach may be adopted. The position at which the cleaning layer 2 is pierced with the distal tip portion 22 of the probe needle 21 is gradually moved, e.g., the fixing seat is gradually moved in its horizontal direction so that portions of the cleaning layer 2 where the foreign matter 23 does not remain may be sequentially pierced with the distal tip portion 22 of the probe needle 21.

### 4. Continuity Test Apparatus

A continuity test apparatus of the present invention is cleaned by the cleaning method of the present invention. That is, the continuity test apparatus of the present invention is such that foreign matter adhering to a probe needle of the probe card of the continuity test apparatus is effectively removed by the cleaning method as described above. According to the cleaning method of the present invention, the foreign matter adhering to the probe needle can be effectively removed without the abrasion of the probe needle. Accordingly, with regard to a continuity test apparatus including a probe card provided with several tens of thousands of probe needles, this kind of continuity test apparatus being generally used for the refinement of a chip in recent years, foreign matter adhering to the probe needle of the probe card can be removed in an extremely effective fashion, thereby enabling effective maintenance and management thereof of the continuity test apparatus.

### 5. Method of Producing the Cleaning Sheet of the Present Invention

The cleaning sheet of the present invention can be produced by any appropriate method. For example, the cleaning sheet can be produced by: applying the material constituting the cleaning layer onto any appropriate substrate or sheet; and subjecting the applied material to curing or the like to form the cleaning layer. Examples of the substrate include a support and a conveying member. The sheet is, for example, a sheet subjected to a release treatment. Any appropriate method can be adopted as the method for the application. Examples of such an application method include casting, spin coating, and roll coating. Any appropriate means can be adopted as a means for the curing. Examples of such curing means include natural curing, curing through irradiation with an active energy ray, and thermal curing.

When the cleaning sheet of the present invention has the pressure-sensitive adhesive layer, the cleaning sheet can be produced, for example, by: applying a material constituting the pressure-sensitive adhesive layer onto any appropriate substrate or sheet; and subjecting the applied material to curing or the like to form the pressure-sensitive adhesive layer. Examples of the substrate include the cleaning layer of the present invention, a support, and a conveying member. The sheet is, for example, a sheet subjected to a release treatment. Any appropriate method can be adopted as the application method. Examples of the application method include casting, spin coating, and roll coating. Any appropriate means can be adopted as the means for the curing. Examples of the curing means include natural curing, curing through irradiation with an active energy ray, and thermal curing.

### 6. Method of Producing the Cleaning Member of the Present Invention

The cleaning member of the present invention can be produced by any appropriate method. For example, the cleaning member can be produced by attaching the cleaning sheet of the present invention onto the conveying member with any appropriate means. Alternatively, the cleaning member can be produced by sequentially building, on the conveying member, layers constructing the cleaning sheet of the present invention.

Hereinafter, the present invention will be described in more detail with reference to the Examples. Note that the present invention is not limited to the Examples.

### <<Arithmetic Average Roughness Ra>>

An arithmetic average roughness Ra in conformity with JIS-B-0601 was measured with a stylus surface roughness-measuring apparatus (DEKTAK8 manufactured by Veeco). A stylus was moved at a measuring speed of 1 μm/s and a pressing force of 1 mg. A measuring range was set to 500 μm. The tip portion of the stylus had a curvature of 2 μm and the stylus used here was made of diamond.

### <<Dynamic Hardness>>

A dynamic hardness was measured with a microhardness meter (DUH-210 manufactured by Shimadzu Corporation). A load was set to 0.98 mN.

### <<Tensile Storage Modulus of Elasticity>>

A measuring object was cut out into a slot shape having a width of 10 mm with a box cutter. Its tensile storage moduli of elasticity at −50 to 250° C. were measured with a solid viscoelasticity-measuring apparatus (RSA-III manufactured by Rheometric Scientific) at a frequency of 1 Hz, and then the object was evaluated for its tensile storage modulus of elasticity at 23° C.

### <<90° Peel Strength>>

A measuring object was backed with a pressure-sensitive adhesive tape (manufactured by Nitto Denko Corporation, trade name: BT-315) and then cut out into a size measuring 10 mm by 100 mm. Subsequently, the resultant tape-backed measuring object was attached onto a silicon wafer (for example, a mirror surface of the silicon wafer) on a hot plate at 50° C. by reciprocating a 2-kg roller once. Subsequently, the resultant attached measuring object was left to stand under a normal-temperature environment for 20 min without being treated. In this manner, a test piece was produced. Next, the attached semiconductor wafer was fixed at 90° and then a 90° peel strength was measured with a tensile tester (AGS-H manufactured by Shimadzu Corporation).

### <<Cleaning Evaluation Test>>

In a prober, a probe card (having 20 probe needles) was brought into continuous contact with an aluminum-deposited wafer 10,000 times in an overdrive amount of 60 μm. After completion of the 10,000 contacts, the probe card was brought into contact with a cleaning sheet mounted on a stage three times in an overdrive amount of 50 μm so that the cleaning of the probe needles was performed. It should be noted that when the tips of the probe needles of the probe card were brought into contact with the cleaning sheet, the cleaning was performed by moving the stage to prevent each of the probe needles from contacting the same site. After the completion of the cleaning, the tips of the probe needles were observed with an optical microscope to determine whether or not foreign matter adhering to the needles remained.

Further, the tips of the needles were observed with the optical microscope to determine whether or not a part of the cleaning layer adhered to the tips of the probe needles, for example, whether or not a part of the cleaning layer was transferred onto the probe needles.

### Example 1

### Cleaning Layer Solution A

1.0 part by weight of a polyisocyanate compound (manufactured by Nippon Polyurethane Industry Co., Ltd., trade name: Coronate L) was uniformly mixed into 100 parts by weight of an acrylic acid ester-based polymer (manufactured by Nagase ChemteX Corporation, trade name: SG-70L). In this manner, a cleaning layer solution A was obtained.

### (Pressure-Sensitive Adhesive Layer Solution A)

A 200 g mixture comprising 73 parts by weight of 2-ethylhexyl acrylate, 10 parts by weight of n-butyl acrylate, 15 parts by weight of N,N′-dimethylacrylamide, 5 parts by weight of acrylic acid, 0.15 parts by weight of 2,2′-azobisisobutyronitrile as a polymerization initiator, and 100 parts by weight of ethyl acetate was loaded into a three-necked flask-type reaction vessel having an internal volume of 500 ml provided with a temperature gauge, a stirring machine, a nitrogen-introducing pipe, and a reflux condenser while being compounded. The mixture was stirred while nitrogen gas was introduced into the vessel for about 1 hour so that air in the vessel was replaced with nitrogen. After that, the temperature in the vessel was increased to 58° C. The mixture was held at that state for about 4 hours and then subjected to polymerization. In this manner, a pressure-sensitive adhesive polymer solution was obtained. 3.0 parts by weight of a polyisocyanate compound (manufactured by Nippon Polyurethane Industry Co., Ltd., trade name: Coronate L) were uniformly mixed into 100 parts by weight of the pressure-sensitive adhesive polymer solution. In this manner, a pressure-sensitive adhesive layer solution A was obtained.

### (Cleaning Sheet A)

The pressure-sensitive adhesive layer solution A was applied to the release-treated surface of a separator, one surface of which was formed of a polypropylene film (manufactured by Mitsubishi Chemical Corporation, trade name: MRF25), so that the solution formed a layer having a thickness of 7 μm after drying. A continuous polyester film (manufactured by Mitsubishi Chemical Corporation, trade name: N100C25) was laminated on the pressure-sensitive adhesive layer thus formed. Further, the cleaning layer solution A was applied onto the film so as to form a layer having a thickness of 150 μm after drying. Attached to the surface of the resultant layer was the silicone-treated surface of a protective film (manufactured by Mitsubishi Chemical Corporation, trade name: MRF50) formed of a long-chain polyester film, one surface of which was treated with a silicone-based releasing agent. In this manner, a cleaning sheet A was obtained.

### (Cleaning Member A)

The release film on the side of the pressure-sensitive adhesive layer of the cleaning sheet A was released, and then the remaining sheet was attached to the mirror surface of a 200-mm silicon wafer with a hand roller. After that, the separator on the side of the cleaning layer was released. In this manner, a cleaning member A was produced.

### (Cleaning Layer A)

The cleaning layer solution A was applied to the release-treated surface of a protective film (manufactured by Mitsubishi Chemical Corporation, trade name: MRF50) formed of a long-chain polyester film, one surface of which was treated with a silicone-based releasing agent, so that the solution formed a layer having a thickness of 150 μm after drying. Attached to the surface of the formed layer was the release-treated surface of a protective film (manufactured by Mitsubishi Chemical Corporation, trade name: MRF50) formed of a long-chain polyester film, one surface of which was treated with a silicone-based releasing agent. In this manner, a cleaning sheet AA was obtained. The protective films on both surfaces were released from the cleaning sheet AA. In this manner, a cleaning layer A was obtained.

### (Evaluation)

The surface of the cleaning layer of the cleaning member A was subjected to a cleaning evaluation test by measuring the arithmetic average roughness Ra and dynamic hardness of the surface of the cleaning layer of the cleaning member A, and by measuring the tensile storage modulus of elasticity and 90° peel strength of the cleaning layer A. Table 1 shows the results.

### Example 2

### Cleaning Layer Solution A

The cleaning layer solution A was obtained in the same manner as in Example 1.

### (Cleaning Member B)

The cleaning layer solution A was applied onto the mirror surface of an 8-inch silicon wafer so as to form a layer having a thickness of 150 μm after drying with a spin coater. In this manner, a cleaning member B having a cleaning layer B was obtained.

### (Cleaning Layer B)

The cleaning layer was released from the cleaning member B. In this manner, the cleaning layer B was obtained.

### (Evaluation)

The surface of the cleaning layer of the cleaning member B was subjected to a cleaning evaluation test by measuring the arithmetic average roughness Ra and dynamic hardness of the surface of the cleaning layer of the cleaning member B, and by measuring the tensile storage modulus of elasticity and 90° peel strength of the cleaning layer B. Table 1 shows the results.

### Example 3

### Cleaning Layer Solution C

1.6 parts by weight of a polyisocyanate compound (manufactured by Nippon Polyurethane Industry Co., Ltd., trade name: Coronate L) were uniformly mixed into 100 parts by weight of an acrylic acid ester-based polymer (manufactured by Nagase ChemteX Corporation, trade name: SG-600TEA). In this manner, a cleaning layer solution C was obtained.

### (Cleaning Sheet C)

The pressure-sensitive adhesive layer solution A obtained in Example 1 was applied to the release-treated surface of a separator, one surface of which was formed of a polypropylene film (manufactured by Mitsubishi Chemical Corporation, trade name: MRF25), so that the solution formed a layer having a thickness of 7 μm after drying. A continuous polyester film (manufactured by Mitsubishi Chemical Corporation, trade name: N100C25) was laminated on the pressure-sensitive adhesive layer thus formed. Further, the cleaning layer solution C was applied onto the film so as to form a layer having a thickness of 150 μm after drying. Attached to the surface of the resultant layer was the silicone-treated surface of a protective film (manufactured by Mitsubishi Chemical Corporation, trade name: MRF50) formed of a long-chain polyester film, one surface of which was treated with a silicone-based releasing agent. In this manner, a cleaning sheet C was obtained.

### (Cleaning Member C)

The release film on the side of the pressure-sensitive adhesive layer of the cleaning sheet C was released, and then the remaining sheet was attached to the mirror surface of a 200-mm silicon wafer with a hand roller. After that, the separator on the side of the cleaning layer was released. In this manner, a cleaning member C was produced.

### (Cleaning Layer C)

The cleaning layer solution C was applied to the release-treated surface of a protective film (manufactured by Mitsubishi Chemical Corporation, trade name: MRF50) formed of a long-chain polyester film, one surface of which was treated with a silicone-based releasing agent, so that the solution formed a layer having a thickness of 150 μm after drying. Attached to the surface of the resultant layer was the release-treated surface of a protective film (manufactured by Mitsubishi Chemical Corporation, trade name: MRF50) formed of a long-chain polyester film, one surface of which was treated with a silicone-based releasing agent. In this manner, a cleaning sheet CC was obtained. The protective films on both surfaces were released from the cleaning sheet CC. In this manner, a cleaning layer C was obtained.

### (Evaluation)

The surface of the cleaning layer of the cleaning member C was subjected to a cleaning evaluation test by measuring the arithmetic average roughness Ra and dynamic hardness of the surface of the cleaning layer of the cleaning member C, and by measuring the tensile storage modulus of elasticity and 90° peel strength of the cleaning layer C. Table 1 shows the results.

### Example 4

### Cleaning Layer Solution D

1.5 parts by weight of a catalyst (manufactured by Dow Corning Toray Co., Ltd., trade name: SRX 212 CATALYST) were uniformly mixed into 100 parts by weight of an addition reaction curable silicone adhesive (manufactured by Dow Corning Toray Co., Ltd., trade name: SD-4587L). Two kinds of addition reaction curable silicone rubbers (manufactured by Dow Corning Toray Co., Ltd., trade names: SILASCON RTV 4086A and SILASCON RTV 4086B) were added in an amount of 1 part by weight each to the mixture, and then the contents were uniformly mixed. In this manner, a cleaning layer solution D was obtained.

### (Cleaning Sheet D)

The pressure-sensitive adhesive layer solution A obtained in Example 1 was applied to the release-treated surface of a separator, one surface of which was formed of a polypropylene film (manufactured by Mitsubishi Chemical Corporation, trade name: MRF25), so that the solution formed a layer having a thickness of 7 μm after drying. A continuous polyester film (manufactured by Mitsubishi Chemical Corporation, trade name: N100C25) was laminated on the pressure-sensitive adhesive layer thus formed. Further, the cleaning layer solution D was applied onto the film so as to form a layer having a thickness of 150 μm after drying. Attached to the surface of the resultant layer was the fluorine-treated surface of a protective film (manufactured by NIPPA CO., LTD., trade name: SS4C) formed of a long-chain polyester film, one surface of which was treated with a fluorine-based releasing agent. In this manner, a cleaning sheet D was obtained.

### (Cleaning Member D)

The release film on the side of the pressure-sensitive adhesive layer of the cleaning sheet D was released, and then the remaining sheet was attached to the mirror surface of a 200-mm silicon wafer with a hand roller. After that, the separator on the side of the cleaning layer was released. In this manner, a cleaning member D was produced.

### (Cleaning Layer D)

The cleaning layer solution D was applied to the release-treated surface of a protective film (manufactured by NIPPA CO., LTD., trade name: SS4C) formed of a long-chain polyester film, one surface of which was treated with a fluorine-based releasing agent, so that the solution formed a layer having a thickness of 150 μm after drying. Attached to the surface of the resultant layer was the release-treated surface of a protective film (manufactured by NIPPA CO., LTD., trade name: SS4C) formed of a long-chain polyester film, one surface of which was treated with a fluorine-based releasing agent. In this manner, a cleaning sheet DD was obtained. The protective films on both surfaces were released from the cleaning sheet DD. In this manner, a cleaning layer D was obtained.

### (Evaluation)

The surface of the cleaning layer of the cleaning member D was subjected to a cleaning evaluation test by measuring the arithmetic average roughness Ra and dynamic hardness of the surface of the cleaning layer of the cleaning member D, and by measuring the tensile storage modulus of elasticity and 90° peel strength of the cleaning layer D. Table 1 shows the results.

### Example 5

### Cleaning Layer Solution E

1.5 parts by weight of a catalyst (manufactured by Dow Corning Toray Co., Ltd., trade name: SRX 212 CATALYST) were uniformly mixed into 100 parts by weight of an addition reaction curable silicone adhesive (manufactured by Dow Corning Toray Co., Ltd., trade name: SD-4587L). In this manner, a cleaning layer solution E was obtained.

### (Cleaning Sheet E)

The pressure-sensitive adhesive layer solution A obtained in Example 1 was applied to the release-treated surface of a separator, one surface of which was formed of a polypropylene film (manufactured by Mitsubishi Chemical Corporation, trade name: MRF25), so that the solution formed a layer having a thickness of 7 μm after drying. A continuous polyester film (manufactured by Mitsubishi Chemical Corporation, trade name: N100C25) was laminated on the pressure-sensitive adhesive layer thus formed. Further, the cleaning layer solution E was applied onto the film so as to form a layer having a thickness of 150 μm after drying. Attached to the surface of the resultant layer was the fluorine-treated surface of a protective film (manufactured by NIPPA CO., LTD., trade name: SS4C) formed of a long-chain polyester film, one surface of which was treated with a fluorine-based releasing agent. In this manner, a cleaning sheet E was obtained.

### (Cleaning Member E)

The release film on the side of the pressure-sensitive adhesive layer of the cleaning sheet E was released, and then the remaining sheet was attached to the mirror surface of a 200-mm silicon wafer with a hand roller. After that, the separator on the side of the cleaning layer was released. In this manner, a cleaning member E was produced.

### (Cleaning Layer E)

The cleaning layer solution E was applied to the release-treated surface of a protective film (manufactured by NIPPA CO., LTD., trade name: SS4C) formed of a long-chain polyester film, one surface of which was treated with a fluorine-based releasing agent, so that the solution formed a layer having a thickness of 150 μm after drying. Attached to the surface of the resultant layer was the release-treated surface of a protective film (manufactured by NIPPA CO., LTD., trade name: SS4C) formed of a long-chain polyester film, one surface of which was treated with a fluorine-based releasing agent. In this manner, a cleaning sheet EE was obtained. The protective films on both surfaces were released from the cleaning sheet EE. In this manner, a cleaning layer E was obtained.

### (Evaluation)

The surface of the cleaning layer of the cleaning member E was subjected to a cleaning evaluation test by measuring the arithmetic average roughness Ra and dynamic hardness of the surface of the cleaning layer of the cleaning member E, and by measuring the tensile storage modulus of elasticity and 90° peel strength of the cleaning layer E. Table 1 shows the results.

### Comparative Example 1

### Cleaning Sheet F

The pressure-sensitive adhesive layer solution A obtained in Example 1 was applied to the release-treated surface of a separator, one surface of which was formed of a polypropylene film (manufactured by Mitsubishi Chemical Corporation, trade name: MRF25), so that the solution formed a layer having a thickness of 7 μm after drying. A continuous polyester film (manufactured by Mitsubishi Chemical Corporation, trade name: N100C25) was laminated on the pressure-sensitive adhesive layer thus formed. Further, the cleaning layer solution A obtained in Example 1 was applied onto the film so as to form a layer having a thickness of 150 μm after drying. Attached to the surface of the resultant layer was the embossing-treated surface of a protective film (PBT manufactured by Idemitsu Kosan Co., Ltd.) formed of a long-chain polyester film, one surface of which was subjected to an embossing treatment. In this manner, a cleaning sheet F was obtained.

### (Cleaning Member F)

The release film on the side of the pressure-sensitive adhesive layer of the cleaning sheet F was released, and then the remaining sheet was attached to the mirror surface of a 200-mm silicon wafer with a hand roller. After that, the separator on the side of the cleaning layer was released. In this manner, a cleaning member F was produced.

### (Cleaning Layer F)

The cleaning layer solution F was applied to the embossing-treated surface of a protective film (PBT manufactured by Idemitsu Kosan Co., Ltd.) formed of a long-chain polyester film, one surface of which was subjected to an embossing treatment so that the solution formed a layer having a thickness of 150 μm after drying. Attached to the surface of the resultant layer was the embossing-treated surface of a protective film (PBT manufactured by Idemitsu Kosan Co., Ltd.) formed of a long-chain polyester film, one surface of which was subjected to an embossing treatment. In this manner, a cleaning sheet FF. was obtained. The protective films on both surfaces were released from the cleaning sheet FF. In this manner, a cleaning layer F was obtained.

### (Evaluation)

The surface of the cleaning layer of the cleaning member F was subjected to a cleaning evaluation test by measuring the arithmetic average roughness Ra and dynamic hardness of the surface of the cleaning layer of the cleaning member F, and by measuring the tensile storage modulus of elasticity and 90° peel strength of the cleaning layer F. Table 1 shows the results.

TABLE 1

| | Arithmetic | | | Adhesion | Presence | Presence or |
|---|---|---|---|---|---|---|
| | average | | Modulus of | strength with | or absence | absence of |
| | roughness | Dynamic | elasticity/Pa | respect to Si | of foreign | transfer of |
| | (Ra)/nm | hardness | (23° C.) | wafer/N/20 mm | matter | cleaning layer |
| Example 1 | 63 | 0.011 | 9.70E+05 | 6.78 | Absent | Absent |
| Example 2 | 7.3 | 0.011 | 9.70E+05 | 6.7 | Absent | Absent |
| Example 3 | 59 | 0.005 | 4.30E+05 | 6 | Absent | Absent |
| Example 4 | 29 | 0.008 | 5.00E+05 | 0.24 | Absent | Absent |
| Example 5 | 35 | 0.006 | 1.62E+05 | 0.78 | Absent | Absent |
| Comparative | 110 | 0.010 | 9.70E+05 | 6.77 | Present | Absent |
| Example 1 | | | | | | |

The cleaning sheet of the present invention can be used for removing foreign matter adhering to a probe needle of a probe card for a continuity test, and can effectively remove the foreign matter adhering to the probe needle without abrading the probe needle.

It should be understood that the embodiments herein are illustrative and not restrictive, since the scope of the invention is defined by the appended claims rather than by the description preceding them. All changes that fall within metes and bounds of the claims or equivalence of such metes and bounds thereof are therefore intended to be embraced by the claims.

What is claimed is:

1. A cleaning sheet, comprising a cleaning layer for removing foreign matter adhering to a probe needle of a probe card for a continuity test, wherein the cleaning layer has an arithmetic average roughness Ra in conformity with JIS-B-0601 of 100 nm or less.

2. The cleaning sheet according to claim 1, wherein the cleaning layer has a dynamic hardness of 0.0001 to 0.1.

3. The cleaning sheet according to claim 1, wherein the cleaning sheet comprises the cleaning layer on one surface of a support.

4. The cleaning sheet according to claim 3, further comprising a pressure-sensitive adhesive layer on a surface of the support opposite to the cleaning layer.

5. A cleaning member, comprising:
a cleaning sheet provided on a conveying member, wherein the cleaning sheet includes a cleaning layer for removing foreign matter adhering to a probe needle of a probe card for a continuity test, wherein the cleaning layer has an arithmetic average roughness Ra in conformity with JIS-B-0601 of 100 nm or less.

6. The cleaning member according to claim 5, wherein the cleaning layer has a dynamic hardness of 0.0001 to 0.1.

7. The cleaning member according to claim 5, wherein the cleaning sheet comprises the cleaning layer on one surface of a support.

8. The cleaning member according to claim 7, further comprising a pressure-sensitive adhesive layer on a surface of the support opposite to the cleaning layer.

9. A cleaning method for a continuity test apparatus, comprising:
conveying a cleaning member into a continuity test apparatus including a probe card for a continuity test, to remove foreign matter adhering to a probe needle of the probe card for a continuity test, wherein the cleaning member includes a cleaning sheet provided on a conveying member, wherein the cleaning sheet includes a cleaning layer for removing foreign matter adhering to a probe needle of a probe card for a continuity test, wherein the cleaning layer has an arithmetic average roughness Ra in conformity with JIS-B-0601 of 100 nm or less.

10. The cleaning method according to claim 9, wherein the cleaning layer has a dynamic hardness of 0.0001 to 0.1.

11. The cleaning method according to claim 9, wherein the cleaning sheet comprises the cleaning layer on one surface of a support.

12. The cleaning method according to claim 11, wherein a pressure-sensitive adhesive layer is formed on a surface of the support opposite to the cleaning layer.

13. A continuity test apparatus, comprising:
a probe card including at least one probe needle for a continuity test, wherein the at least one probe needle is configured such that foreign matter adhered to the probe needle is effectively removed without abrasion of the probe needle by conveying a cleaning member into the continuity test apparatus to remove the foreign matter adhering to a probe needle, wherein the cleaning member includes a cleaning sheet provided on a conveying member, wherein the cleaning sheet includes a cleaning layer for removing the foreign matter, wherein the cleaning layer has an arithmetic average roughness Ra in conformity with JIS-B-0601 of 100 nm or less.
